(19) United States
(12) Patent Application Publication
(10) Pub. No.: US 2014/0052289 A1
(43) Pub. Date: Feb. 20, 2014

(54) MOUNTING APPARATUS, METHOD OF DISPOSING MEMBERS, AND METHOD OF MANUFACTURING SUBSTRATE

(71) Applicant: Sony Corporation, Tokyo (JP)

(72) Inventor: Kenichi Oowada, Aichi (JP)

(73) Assignee: Sony Corporation, Tokyo (JP)

(21) Appl. No.: 13/959,058

(22) Filed: Aug. 5, 2013

(30) Foreign Application Priority Data
Aug. 16, 2012 (JP) 2012-180683

(51) Int. Cl. H01L 21/66

(52) U.S. Cl. CPC H01L 22/12
USPC 700/121

(57) ABSTRACT

A mounting apparatus includes a mounting head, an image pickup unit, and a height measurement unit. The mounting head has a placement member that places an electronic component on a substrate and is movable in a first direction and a second direction perpendicular to the first direction. The image pickup unit is disposed on a position where the image pickup unit is movable along with a movement of the mounting head and takes an image of an alignment mark on the substrate. The height measurement unit is disposed in an area surrounded by one or more lines that are parallel to the first direction and pass through at least one of positions of the placement member and the image pickup unit and one or more lines that are parallel to the second direction and pass through at least one of the positions thereof and measures a height of the substrate.

### CROSS REFERENCES TO RELATED APPLICATIONS

The present application claims priority to Japanese Priority Patent Application JP 2012-180683 filed in the Japan Patent Office on Aug. 16, 2012, the entire content of which is hereby incorporated by reference.

### BACKGROUND

The present disclosure relates to a technology such as a mounting apparatus that holds an electronic component to place the electronic component on a substrate.

From the past, a mounting apparatus that mounts various electronic components such as a resistor, a capacitor, and an inductor on a substrate is widely known.

The mounting apparatus of this type includes a conveyance unit that conveys a substrate, a supply unit that supplies an electronic component, and a mounting head having a suction nozzle that sucks the electronic component supplied from the supply unit and places the sucked electronic component on a substrate. Further, the mounting apparatus is provided with a movement mechanism that moves the mounting head in XY directions, a substrate camera that takes an image of an alignment mark provided on the substrate, and the like. Generally, the substrate camera is attached to the mounting head and can be moved according to the movement of the mounting head.

When the electronic component is placed on the substrate, a problem of warp of a substrate may arise. That is, if the substrate warps, there is a problem in that a placement error is likely to occur when the suction nozzle is moved in a vertical direction to place the electronic component on the substrate.

In view of this, these days, a height measurement sensor that measures the height of an upper surface of a substrate is provided to a mounting apparatus (see, for example, Japanese Patent Application Laid-open No. 2009-27015). In the mounting apparatus of this type, the height of a substrate is measured by the height measurement sensor, and in accordance with the height measured, a placement position of an electronic component is corrected in a height direction. Then, at the height corrected, the mounting apparatus is placed on the substrate.

### SUMMARY

Generally, a height measurement sensor is disposed on a position from which the sensor can be moved in accordance with a movement of a mounting head. Here, it is necessary to make three members of a suction nozzle, a substrate camera, and the height measurement sensor movable to all positions on the substrate in XY directions.

Therefore, if the height measurement sensor is not disposed on an appropriate position in positional relationship with the suction nozzle and the substrate camera, there is a problem in that a movement stroke of the mounting head becomes larger.

In view of the above-mentioned circumstances, it is desirable to provide a technology capable of suppressing an increase in movement stroke of a mounting head by disposing a height measurement unit at an appropriate position in positional relationship with a placement member and an image pickup unit.

According to an embodiment of the present disclosure, there is provided a mounting apparatus including a mounting head, an image pickup unit, and a height measurement unit.

The mounting head has a placement member that places an electronic component on a substrate, and the mounting head is movable in a first direction and a second direction perpendicular to the first direction in a plane.

The image pickup unit is disposed on a position where the image pickup unit is movable along with a movement of the mounting head and configured to take an image of an alignment mark provided on the substrate.

The height measurement unit is disposed in an area surrounded by one or more lines that are parallel to the first direction and pass through at least one of a position of the placement member and a position of the image pickup unit and one or more lines that are parallel to the second direction and pass through at least one of the position of the placement member and the position of the image pickup unit and configured to measure a height of the substrate.

In the mounting apparatus according to the embodiment of the present disclosure, the height measurement unit is disposed on an appropriate position in the positional relationship with the placement member and the image pickup unit, so it is possible to prevent the movement stroke of the mounting head from being increased.

In the mounting apparatus, the placement member, the image pickup unit, and the height measurement unit may be linearly arranged along one of the first direction and the second direction.

With this structure, it is possible to appropriately reduce the movement stroke of the mounting head.

In the mounting apparatus, the substrate may be conveyed along the second direction.

In this case, the placement member, the image pickup unit, and the height measurement unit may be linearly arranged along the first direction.

In the mounting apparatus, the substrate may be conveyed along the second direction.

In this case, the placement member, the image pickup unit, and the height measurement unit may be linearly arranged along the second direction.

The mounting apparatus may further include a movement body which is movable in the first direction and the second direction and to which the mounting head is attached.

In this case, the image pickup unit and the height measurement unit may be disposed on a lower position of the movement body.

By attaching the image pickup unit and the height measurement unit to the lower side of the movement body, it is possible to effectively use dead space on the lower side of the movement body.

According to another embodiment of the present disclosure, there is provided a method of disposing members. The method includes configuring a mounting head having a placement member that places an electronic component on a substrate so that the mounting head is movable in a first direction and a second direction perpendicular to the first direction in a plane.

An image pickup unit that takes an image of an alignment mark provided on the substrate is disposed on a position where the image pickup unit is movable along with a movement of the mounting head.

A height measurement unit that measures a height of the substrate is disposed in an area surrounded by one or more lines that are parallel to the first direction and pass through at least one of a position of the placement member and a position of the image pickup unit and one or more lines that are parallel to the second direction and pass through at least one of the position of the placement member and the position of the image pickup unit.

According to another embodiment of the present disclosure, there is provided a method of manufacturing a substrate. The method includes measuring a height of a substrate by a height measurement unit of a mounting apparatus. The mounting apparatus includes a mounting head which has a placement member that places an electronic component on the substrate and which is movable in a first direction and a second direction perpendicular to the first direction in a plane, an image pickup unit disposed on a position where the image pickup unit is movable along with a movement of the mounting head and configured to take an image of an alignment mark provided on the substrate, and the height measurement unit disposed in an area surrounded by one or more lines that are parallel to the first direction and pass through at least one of a position of the placement member and a position of the image pickup unit and one or more lines that are parallel to the second direction and pass through at least one of the position of the placement member and the position of the image pickup unit.

An electronic component is placed on the substrate by the placement member in accordance with the height of the substrate measured.

As described above, according to the present disclosure, it is possible to provide the technology capable of suppressing the increase in the movement stroke of the mounting head.

These and other objects, features and advantages of the present disclosure will become more apparent in light of the following detailed description of best mode embodiments thereof, as illustrated in the accompanying drawings.

Additional features and advantages are described herein, and will be apparent from the following Detailed Description and the figures.

### BRIEF DESCRIPTION OF THE FIGURES

FIG. 1 is a front view showing a mounting apparatus according to an embodiment of the present disclosure;

FIG. 2 is a side view showing the mounting apparatus;

FIG. 3 is a top view showing the mounting apparatus;

FIG. 4 is a block diagram showing the structure of the mounting apparatus;

FIG. 5 is a side enlarged view showing a mounting head of the mounting apparatus;

FIG. 6 is a bottom view showing the mounting head and a movement body;

FIG. 7 is a diagram for explaining a movable area of a suction nozzle, a substrate camera, and a height sensor 7 on a substrate according to the embodiment;

FIG. 8 is a diagram for explaining a movable area of a suction nozzle, a substrate camera, and a height sensor 7 on a substrate according to a comparative example; and

FIG. 9 is a diagram for explaining a position of the height sensor with respect to positions of the suction nozzle and the substrate camera.

### DETAILED DESCRIPTION

Hereinafter, an embodiment of the present disclosure will be described with reference to the drawings.

(Entire structure of mounting apparatus 100 and structures of units Thereof)

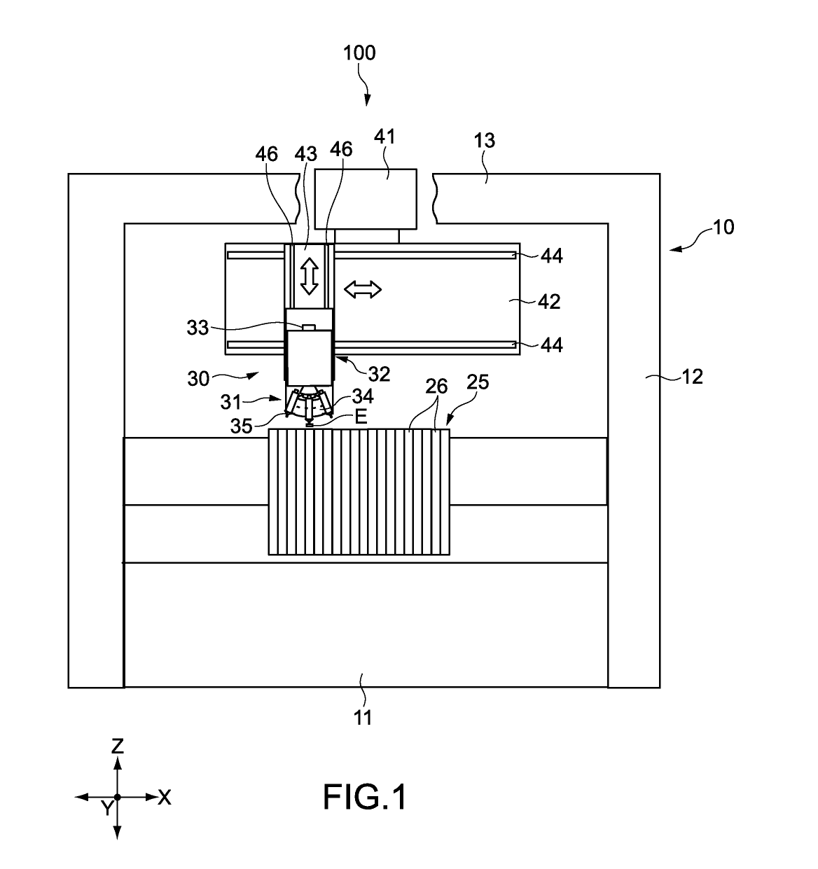

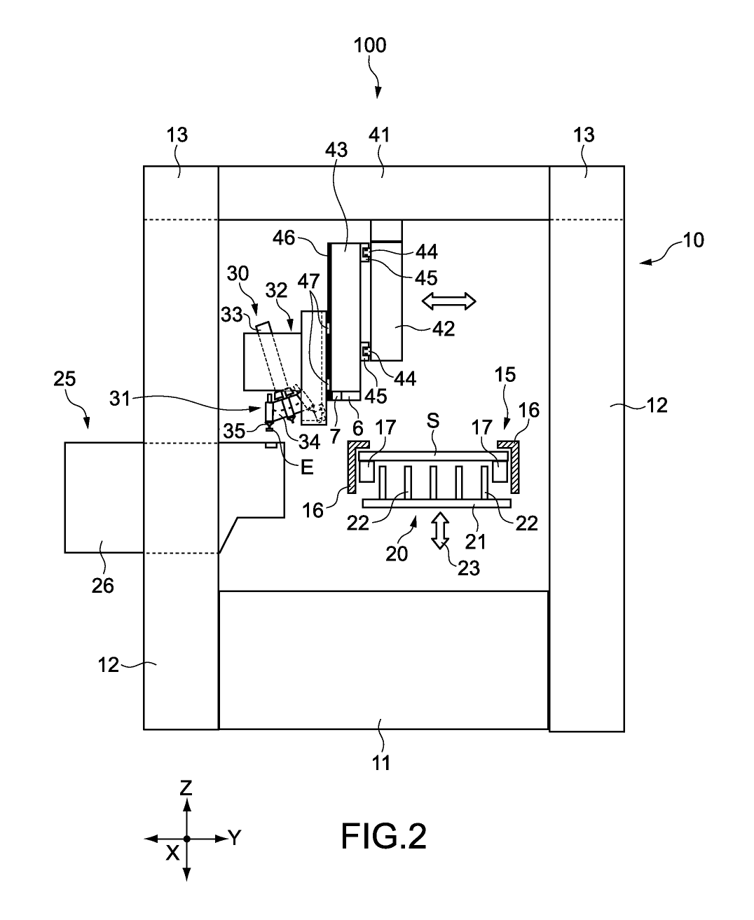

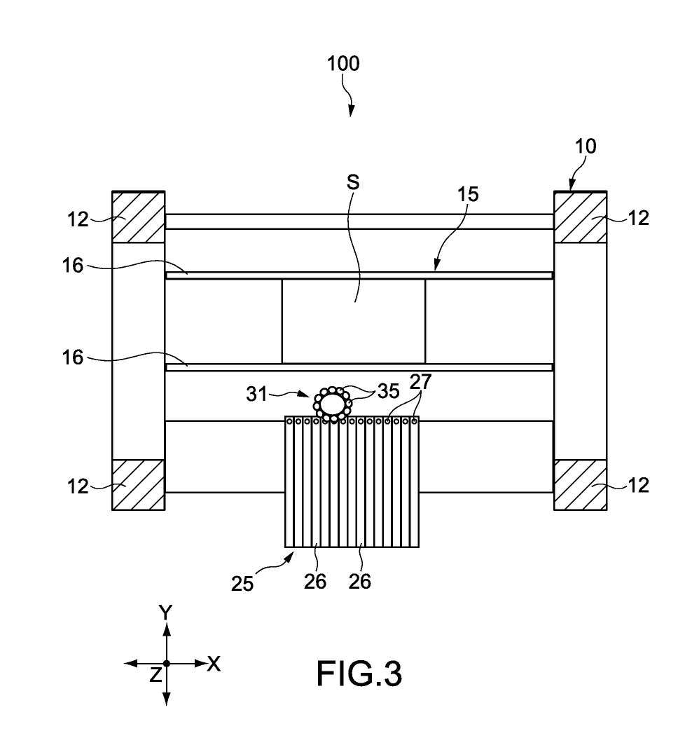

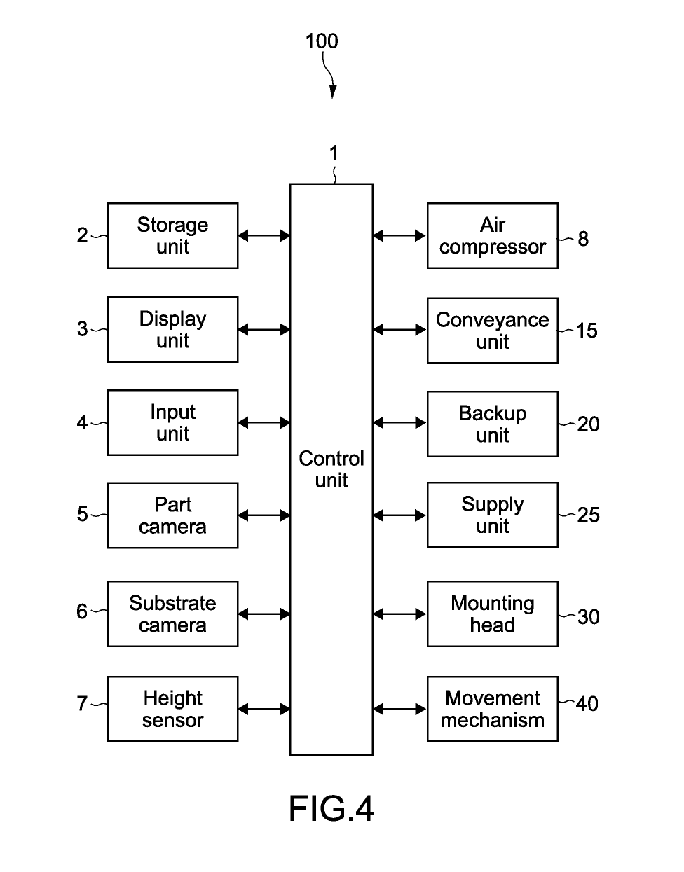

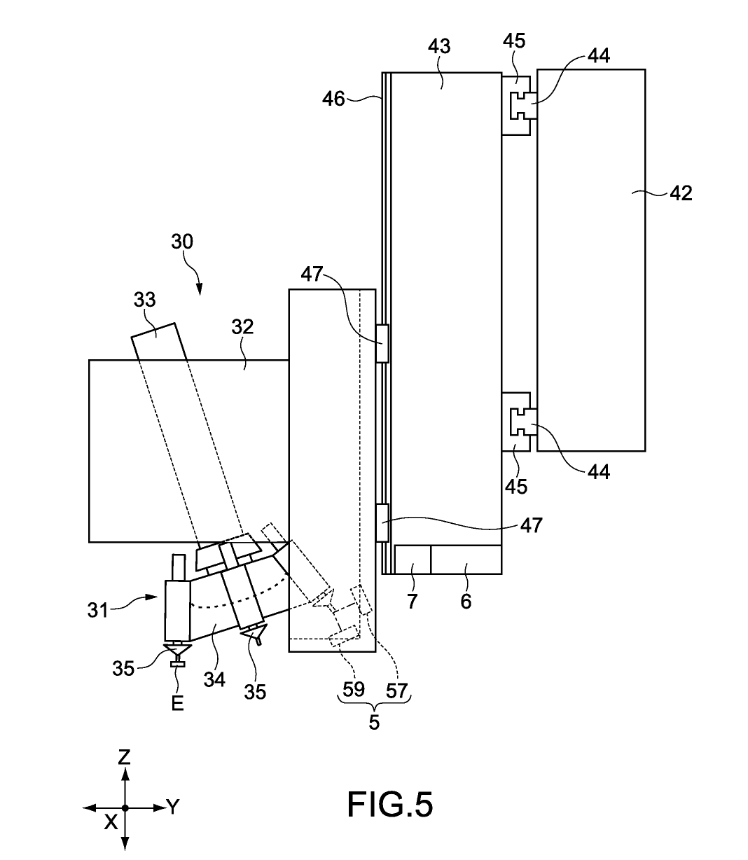

FIG. 1 is a front view showing a mounting apparatus 100 according to an embodiment of the present disclosure, FIG. 2 is a side view showing the mounting apparatus 100, and FIG. 3 is a top view showing the mounting apparatus 100. FIG. 4 is a block diagram showing the structure of the mounting apparatus 100. FIG. 5 is a side enlarged view showing a mounting head 30 of the mounting apparatus 100.

With reference to FIGS. 1 to 3, the mounting apparatus 100 is provided with a frame structure 10, a conveyance unit 15, a backup unit 20, a supply unit 25, the mounting head 30, and a movement mechanism 40. The mounting apparatus 100 is further provided with a part camera 5, a substrate camera 6 (image pickup unit), and a height sensor 7 (height measurement unit).

With reference to FIG. 4, the mounting apparatus 100 is further provided with a control unit 1, a storage unit 2, a display unit 3, an input unit 4, an air compressor 8, and the like.

The frame structure 10 (see, FIGS. 1 to 3) has a base 11 provided on a bottom portion thereof, four vertical frames 12 fixed to the base 11, and two transverse frames 13 extended over upper portions of the vertical frames 12 along an X axis direction.

The conveyance unit 15 (see, FIGS. 2 to 4) is provided along the X axis direction in the mounting apparatus 100 and conveys a substrate S in the X axis direction. The conveyance unit 15 includes guides 16 provided along the X axis direction and conveyor belts 17 provided on inner sides of the guides 16. By driving the conveyor belts 17, the conveyance unit 15 conveys the substrate S, thereby moving the substrate S and positioning the substrate S at a predetermined position and passing the substrate S on which an electronic component E has been mounted to another apparatus.

One of the two guides 16 can be moved in the Y axis direction. With this structure, it is possible to adjust a distance between the two guides 16 in accordance with a size of the substrate S.

The guides 16 are each formed so that an upper end portion thereof is bent inwards, and the upper end portions of the guide units 16 are capable of supporting the substrate S from above when the substrate S is moved upwards by the backup unit 20.

The backup unit 20 (see, FIGS. 2 and 4) supports the substrate S conveyed to the predetermined position by the conveyance unit 15 from below. The backup unit 20 includes a backup plate 21, a plurality of support pins 22 uprightly provided on the backup plate 21, and a plate lifting and lowering mechanism 23 that lifts and lowers the backup plate 21.

When the conveyance unit 15 conveys the substrate S on which the electronic component E is to be mounted to the predetermined position, the plate lifting and lowering mechanism 23 moves the backup plate 21 upwards. As a result, the substrate S is sandwiched between the backup unit 20 and the upper end portions of the guides 16, thereby fixing the substrate S to the predetermined position. In this state, the electronic component E is mounted on the substrate S.

The supply unit 25 (see, FIGS. 1 to 4) includes a plurality of tape cassettes 26 arranged along the X axis direction. The tape cassettes 26 can be attached to and detached from the mounting apparatus 100. The tape cassettes 26 each store a carrier tape (not shown) therein. The tape cassettes 26 each include a reel around which the carrier tape is wound and a feed mechanism that feeds the carrier tape by step feeding.

In the carrier tape, for example, the electronic components E of the same type such as a resistor, a capacitor, an inductor, and an IC (integrated circuit) chip are stored. On an upper surface of an end portion (on the center side of the mounting apparatus 100) of the tape cassette 26, a supply window 27 is formed, and via the supply window 27, the electronic components E are supplied to the mounting head 30.

The movement mechanism 40 (see, FIGS. 1, 2, 4, and 5) is capable of moving the mounting head 30 in the X, Y, and Z axis directions.

The movement mechanism 40 has a Y axis beam 41 extended along the Y axis direction with respect to the two transverse frames 13 of the frame structure 10 and an X axis beam 42 attached on a lower position of the Y axis beam 41 so as to be movable in the Y axis direction. Further, the movement mechanism 40 has a movement body 43 attached to the X axis beam 42 so as to be movable in the X axis direction.

The X axis beam 42 is moved in the Y axis direction by the drive of a Y axis drive mechanism (not shown) provided to the Y axis beam 41. As the Y axis drive mechanism, for example, a ball screw drive mechanism, a belt drive mechanism, or the like is used (the same holds true for an X axis drive mechanism and a Z axis drive mechanism to be described later). The X axis beam 42 has an elongated shape in the X axis direction, and on a front surface side of the X axis beam 42, two rails 44 are provided in parallel to each other along the X axis direction. On a back surface side of the movement body 43, a plurality of slide members 45 which can be slid on the rails 44 are provided so as to correspond to the rails 44.

To the X axis beam 42, the X axis drive mechanism (not shown) for moving the movement body 43 in the X axis direction is provided. When the X axis drive mechanism is driven, the plurality of slide members 45 are slid on the two rails 44, and the movement body 43 is moved in the X axis direction. Here, the movement body 43 is provided to the X axis beam 42, which is capable of being moved in the Y axis direction, so as to be movable in the X axis direction and therefore can be moved in the X and Y axis directions.

On a front side surface of the movement body 43, two rails 46 are provided along the Z axis direction in parallel to each other. On a back side surface of the mounting head 30, a plurality of slide members 47 capable of being slid on the rails 46 are provided so as to correspond to the rails 46.

To the movement body 43, the Z axis drive mechanism (not shown) for moving the mounting head 30 in the Z axis direction is provided. When the Z axis drive mechanism is driven, the plurality of slide members 47 are slid on the two rails 46, thereby moving the mounting head 30 in the Z axis direction.

Here, the mounting head 30 is attached so as to be movable in the Z axis direction with respect to the movement body 43 movable in the X and Y axis directions. Therefore, the mounting head 30 can be moved in the X axis direction (conveyance direction of the substrate S: second direction), the Y axis direction (direction perpendicular to the conveyance direction of the substrate S: first direction), and the Z axis direction (height direction). By making it possible to move the mounting head 30 in the Z axis direction, it is possible to adjust the height of the mounting head 30 to an appropriate position.

The mounting head 30 (see, FIGS. 1 to 5) includes a head portion 31 and a head support portion 32 that supports the head portion 31. The head portion 31 includes a shaft 33, a turret 34 which is rotatably attached with respect to the shaft 33, and a plurality of suction nozzles 35 (placement member) attached to the turret 34 along a circumferential direction of the turret 34 at equal intervals.

The shaft 33 is tilted from the Z axis direction at a predetermined angle in a YZ plane. By driving a turret drive unit (not shown), the turret 34 is rotated about the shaft 33 tilted in a slanting direction.

The plurality of suction nozzles 35 each suck the electronic component E supplied from the supply window 27 in the supply unit 25 and place the electronic component E sucked on the substrate S. The suction nozzles 35 are attached to the turret 34 so that axis lines of the suction nozzles 35 are tilted with respect to a center axis of the rotation of the turret 34.

The suction nozzles 35 each are supported so as to be movable along the axis line direction with respect to the turret 34. Further, the suction nozzles 35 are supported rotatably with respect to the turret 34. The suction nozzles 35 are each moved in the axis line direction at a predetermined timing and rotated around the axis line at a predetermined timing by driving a nozzle drive unit (not shown).

Out of the plurality of suction nozzles 35, a suction nozzle 35 disposed at a lowermost position (suction nozzle 35 disposed on a left end side in FIGS. 2 and 5) has the axis line along a vertical direction. In the following description, a position where the axis line of the suction nozzle 35 is along the vertical direction is referred to as an operation position. By moving the suction nozzle 35 positioned at the operation position in the vertical direction, the electronic component E is sucked in the supply unit 25, and the electronic component E is placed on the substrate S. The suction nozzle 35 disposed at the operation position is sequentially switched by rotating the turret 34.

The suction nozzles 35 are connected to the air compressor 8 (see, FIG. 4). The suction nozzles 35 can suck and release the electronic component E on the basis of switching of a negative pressure and a positive pressure of the air compressor 8.

The mounting head 30 repeatedly performs a suction process of sucking the electronic components E by the plurality of suction nozzles 35 on the supply unit 25 and a placement process of placing the electronic components E sucked by the suction nozzles 35 on the substrate S. As a result, the electronic components E are mounted on the substrate S to manufacture the substrate S.

To the head support portion 32, the part camera 5 that takes an image of the electronic component E sucked by the suction nozzle 35 is provided. Specifically, the part camera 5 is disposed on a position where the camera can take an image of the electronic component E sucked by the suction nozzle 35 disposed at an uppermost position (suction nozzle 35 disposed on a right end position in FIGS. 2 and 5) out of the plurality of suction nozzles 35.

The part camera 5 includes a first part camera 5a that takes an image of the electronic component E held by the suction nozzle 35 from below and a second part camera 5b that takes an image of the electronic component E held by the suction nozzle 35 from the side thereof.

The image taken by the part camera 5 is transmitted to the control unit 1. On the basis of the image taken by the part camera 5, the control unit 1 determines whether a suction error such as a non-suction error and a stand-up suction error (error of sucking the electronic component E in a stand-up state) occurs or not. Further, on the basis of the image of the electronic component E, the control unit 1 determines an angle (about axis line) at which the electronic component E is sucked with respect to the suction nozzle 35. On the basis of the angle (about axis line) of the electronic component E with respect to the suction nozzle 35, the control unit 1 rotates the suction nozzle 35 about the axis line, and the electronic component E is placed on the substrate S at an appropriate angle.

The control unit 1 (see, FIG. 4) is formed of a CPU (central processing unit), for example. On the basis of various programs stored in the storage unit 2, the control unit 1 performs various operations and performs overall control for units of the mounting apparatus 100.

The storage unit 2 (see, FIG. 4) includes a non-volatile memory in which various programs necessary for the process by the control unit 1 and a volatile memory used as a work area for the control unit 1. The various programs may be read from a portable recording medium such as an optical disk and a semiconductor memory.

The display unit 3 (see, FIG. 4) is formed of a liquid crystal display, an EL (electro-luminescence) display, or the like and displays various pieces of data relating to the mounting apparatus 100 on a screen. The input unit 4 is formed of a touch sensor, a keyboard, a mouse, or the like and inputs various instructions from an operator.

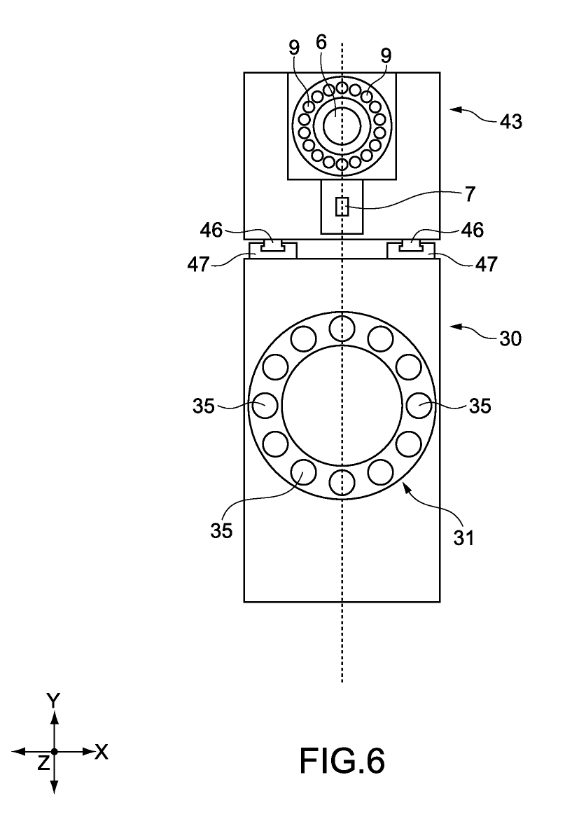

FIG. 6 is a bottom view showing the mounting head 30 and the movement body 43. It should be noted that in FIG. 6, the members such as the part camera 5 are not shown to make the figure more visible.

With reference to FIGS. 5 and 6, on a lower position of the movement body 43, the substrate camera 6 and the height sensor 7 are provided. The substrate camera 6 is disposed on a rear side position on the lower position of the movement body 43, and the height sensor 7 is disposed on a front side position on the lower position of the movement body 43. The substrate camera 6 and the height sensor 7 are provided to the movement body 43 which can be moved in the X and Y axis directions, and thus can be moved in the X and Y axis directions in accordance with the movement of the mounting head 30 by the movement mechanism 40.

In this embodiment, the substrate camera 6 and the height sensor 7 are disposed on the lower position of the movement body 43 as dead space, thereby effectively using the dead space.

The substrate camera 6 can take an image of the alignment marks provided on the substrate S from above. The alignment marks are disposed in the vicinity of two corner portions on a diagonal line. Around the substrate camera 6, a plurality of lights 9 are disposed so as to surround the substrate camera 6. The lights 9 emit light to the substrate S when the substrate camera 6 takes an image of the alignment marks.

After the substrate S is conveyed by the conveyance unit 15 and is fixed to the predetermined position, the movement mechanism 40 is driven, thereby moving the substrate camera 6 to a position above one of the alignment marks. In this state, the substrate camera 6 takes an image of the alignment mark. Then, the movement mechanism 40 is driven, thereby moving the substrate camera 6 to a position above the other alignment mark. In this state, the substrate camera 6 takes an image of the other alignment mark.

The images of the alignment marks taken by the substrate camera 6 are transmitted to the control unit 1. On the basis of the images of the alignment marks received, the control unit 1 recognizes a position in the XY directions where the substrate S is disposed, a tilt of the substrate S around the Z axis, and the like. The control unit 1 places the electronic component E on the substrate S on the basis of the recognized position of the substrate S in the XY directions or the like.

The height sensor 7 is an optical sensor, for example, and irradiates a surface of the substrate 1 with a laser light beam and receives a scattered image from the substrate S, to measure the height of the surface of the substrate S by using the principle of triangulation.

After (or before) the substrate camera 6 takes the images of the alignment marks, the height sensor 7 is moved in the XY directions by the movement mechanism 40, and the height sensor 7 measures the heights of a plurality of points (for example, approximately 10 points) on the substrate S. The information relating to the heights of the plurality of points measured by the height sensor is transmitted to the control unit 1. On the basis of the information, the control unit 1 determines a tendency of the height of the substrate S in the XY directions and three-dimensionally recognizes the height of the substrate S in the XY directions.

When placing the electronic component E on the substrate S, the control unit 1 corrects a position to which the suction nozzle 35 (on the operation position) is lowered on the basis of the height of the substrate S three-dimensionally recognized. Then, the control unit 1 lowers the suction nozzle 35 so that the tip end of the suction nozzle 35 is positioned to the corrected position to which the suction nozzle 35 is to be lowered. As a result, an influence of the warp of the substrate S is eliminated, and it is possible to correctly place the electronic component E on the substrate S.

Alternatively, the following system may be used for a system of measuring the height of the substrate S. First, in the supply unit 25, the electronic components E are sucked by the plurality of suction nozzles 35. After that, the movement mechanism 40 moves the height sensor 7 to a position above the next placement point on the substrate S. Then, the height sensor 7 measures the height of the placement point. Then, the movement mechanism 40 moves the suction nozzle 35 (on the operation position) to a position above the placement point, and the suction nozzle 35 is lowered to the position corresponding to the height of the substrate S. After that, the measurement of the height on the next point and the placement of the electronic component E by the suction nozzle 35 are alternately performed.

(Positional Relationship Among Suction Nozzle 35, Substrate Camera 6, and Height Sensor 7)

Subsequently, the positional relationship among the suction nozzle 35, the substrate camera 6, and the height sensor 7 will be described in detail. It should be noted that the suction nozzle 35 in the description of the positional relationship is the suction nozzle 35 that is moved in the vertical direction and place the electronic component E on the substrate S, that is, the suction nozzle 35 at the operation position.

As shown in FIG. 6, in this embodiment, those three members are disposed in order of the suction nozzle 35, the height sensor 7, and the substrate camera 6 from the front side (lower side in FIG. 6) of the mounting apparatus 100. Further, those three members are linearly arranged along the Y axis direction (direction vertical to the conveyance direction of the substrate S).

In this embodiment, from the viewpoint of a size reduction of the mounting apparatus 100, the positional relationship of those three members is appropriately set. The reason why those three members have the positional relationship shown in FIG. 6 will be described with reference to a comparative example.

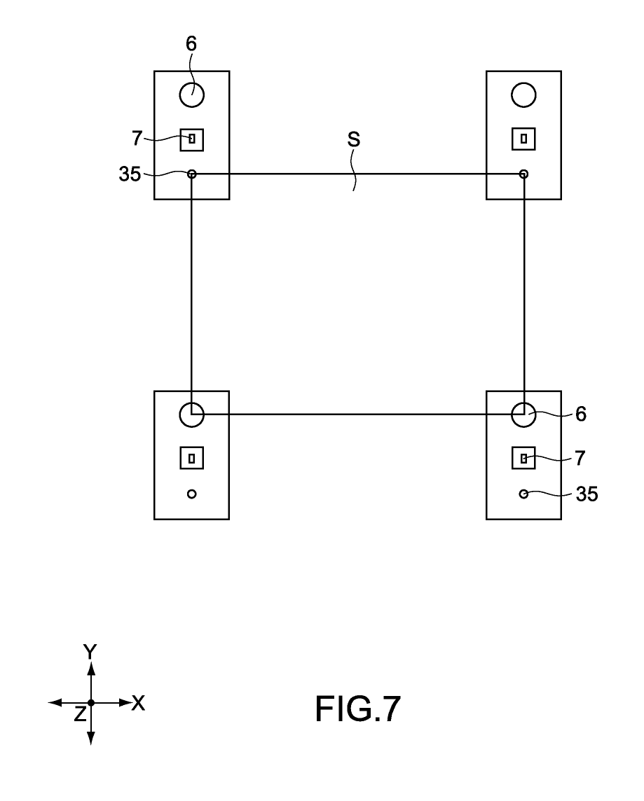

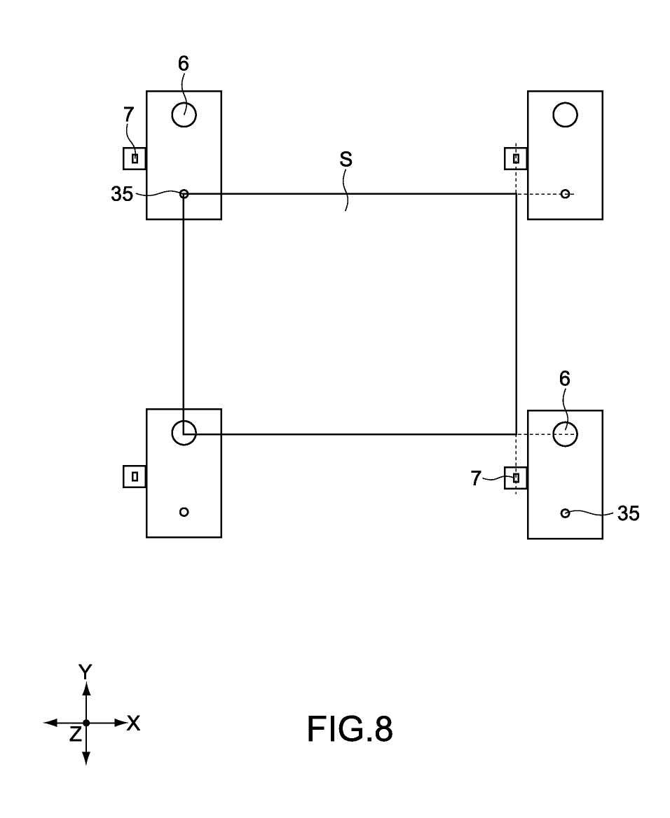

FIG. 7 is a diagram for explaining a movable area of the suction nozzle 35, the substrate camera 6, and the height sensor 7 on the substrate S according to this embodiment. FIG. 8 is a diagram for explaining a movable area of the suction nozzle 35, the substrate camera 6, and the height sensor 7 on the substrate S according to a comparative example.

First, with reference to FIG. 8, the movable area of the suction nozzle 35, the substrate camera 6, and the height sensor 7 on the substrate S in the XY directions according to the comparative example will be described. The comparative example is different from this embodiment in the position of the height sensor 7. The height sensor 7 is provided on an outer circumferential side of the mounting head 30.

Here, it is necessary to configure the suction nozzle 35 so as to be capable of placing the electronic component E on any points on the substrate S. Therefore, the suction nozzle 35 has to be movable above an entire area on the substrate S in the XY directions. Further, the substrate camera 6 has to take images of the alignment marks. The alignment marks may be provided on any position on the substrate S (typically, in the vicinity of corner portions of the substrate S in many cases). Therefore, the substrate camera 6 also has to be movable above the entire area on the substrate S in the XY directions. Further, it is also necessary to configure the height sensor 7 so as to be capable of measuring the height of the substrate S at any points on the substrate S. Therefore, the height sensor 7 also has to be movable above the entire area on the substrate S in the XY directions.

With reference to FIG. 8, conditions for enabling the three members to move above the entire area on the substrate S will be described. Here, in the description of FIG. 8 (and FIG. 7), terms of “front side” and “rear side” are used. The upper side and the lower side in FIG. 8 (and FIG. 7) correspond to the rear side and the front side of the mounting apparatus 100, respectively.

With reference to the upper left part of FIG. 8, conditions for enabling the three members to move above an upper left area of the substrate S will be described. First, explanation about a back-and-forth direction (vertical direction in FIG. 8) will be given. In this case, if the suction nozzle 35 disposed on a front end side (lower side in FIG. 8) out of those three members can move up to an end portion on the rear side (upper side in FIG. 8) of the substrate S, the substrate camera 6 and the height sensor 7 can move to the end portion on the rear side of the substrate S. Explanation about a right-and-left direction will be given. If the suction nozzle 35 or the substrate camera 6 disposed on the right end side out of the three members can move up to a left side end portion of the substrate S, the height sensor 7 can also move to the left side end portion of the substrate S. Thus, to enable the three members to move above the upper left area on the substrate S, it is necessary for the suction nozzle 35 to be capable of moving to a position above the upper left corner portion of the substrate S.

With reference to the lower left part of FIG. 8, if the substrate camera 6 disposed on the rear end side (upper side in FIG. 8) out of the three members can move up to a front side (lower side in FIG. 8) end portion of the substrate S, the suction nozzle 35 and the height sensor 7 also can move to the front side end portion of the substrate S. Further, if the suction nozzle 35 or the substrate camera 6 disposed on the right end side out of the three members can move up to the left side end portion of the substrate S, the height sensor can also move to the left side end portion of the substrate S. Therefore, to enable the three members to move above the lower left area of the substrate S, it is necessary for the substrate camera 6 to be capable of moving to a position above the lower left corner portion of the substrate S.

With reference to the upper right part of FIG. 8, if the suction nozzle 35 disposed on the front end side (lower side in FIG. 8) out of the three members can move up to the rear side (upper side in FIG. 8) end portion of the substrate S, the substrate camera 6 and the height sensor 7 can also move to the rear side end portion of the substrate S. Further, if the height sensor 7 disposed on the left end side out of the three members can move up to the right side end portion of the substrate S, the suction nozzle 35 and the substrate camera 6 can also move to the right side end portion of the substrate S.

With reference to the lower right part of FIG. 8, if the substrate camera 6 disposed on the rear end side (upper side in FIG. 8) out of the three members can move up to the front side (lower side in FIG. 8) end portion of the substrate S, the suction nozzle 35 and the height sensor 7 can also move to the front side end portion. Further, if the height sensor 7 disposed on the left end side out of the three members can move to the right end portion of the substrate S, the suction nozzle 35 and the substrate camera 6 can also move to the right side end portion of the substrate S.

As can be seen from the above description, to enable the three members to move above the right side area of the substrate S, the entire three members (mounting head 30) have to additionally move to the right side. This is because the position of the height sensor 7 is deviated to the left side. A distance by which the entire three members have to move to the right side corresponds to a distance between the suction nozzle 35 (or the substrate camera 6) and the height sensor 7 in the X axis direction.

In the comparative example shown in FIG. 8, the height sensor 7 may be provided not on the left side but on the right side of the mounting head 30. In this case, the entire three members (mounting head 30) have to additionally move to the left side.

In addition, in the comparative example shown in FIG. 8, the height sensor 7 may be disposed on the front side (lower side in FIG. 8) as compared to the suction nozzle 35 or may be disposed on the rear side (upper side in FIG. 8) as compared to the substrate camera 6. In this case, to enable the three members to move above the entire area on the substrate S, the entire three members may have to additionally move in the back-and-forth direction (vertical direction in FIG. 8).

In particular, in the case where the height sensor 7 is disposed on the front side (lower side in FIG. 8) as compared to the suction nozzle 35, an additional movement stroke for moving the entire three members to the rear side (toward a side where the supply unit 25 is not provided) becomes necessary. Here, the entire three members are originally configured so as to be movable to the front side (lower side in FIG. 8) as compared to the substrate S in order to move the suction nozzle 35 on the supply unit 25 provided on the front side (lower side in FIG. 8) as compared to the substrate S. Therefore, even if the height sensor 7 is provided to a position on the rear side (upper side in FIG. 8) as compared to the substrate camera 6, an additional movement stroke for moving the entire three members to the front side (lower side in FIG. 8) may be unnecessary. However, even in such a case, in the case where a distance between the suction nozzle 35 and the height sensor 7 (in the Y axis direction) exceeds a distance between the supply unit 25 and the substrate S (in the Y axis direction), an additional movement stroke for moving the entire three members to the front side becomes necessary.

With reference to FIG. 7, description will be given on the movable area of the suction nozzle 35, the substrate camera 6, and the height sensor 7 on the substrate S according to this embodiment.

With reference to the upper left part of FIG. 7, to enable the three members to move above the upper left area on the substrate S, it is necessary for the suction nozzle 35 to be capable of moving to a position above the upper left corner portion of the substrate S. With reference to the lower left part of FIG. 7, to enable the three members to move above the lower left area on the substrate S, it is necessary for the substrate camera 6 to be capable of moving to a position above the lower left corner portion of the substrate S.

With reference to the upper right part of FIG. 7, to enable the three members to move above the upper right area on the substrate S, it is necessary for the suction nozzle 35 to be capable of moving to a position above the upper right corner portion of the substrate S. With reference to the lower right part of FIG. 7, to enable the three members to move above the lower right area on the substrate S, it is necessary for the substrate camera 6 to be capable of moving to a position above the lower right corner portion of the substrate S.

As is clear from the comparison of FIG. 7 and FIG. 8, in this embodiment, it is possible to reduce the movement stroke of the mounting head 30 in the X axis direction as compared to the comparative example. This is because the suction nozzle 35, the substrate camera 6, and the height sensor 7 are linearly arranged along the Y axis direction, which is the movement direction of the mounting head 30. In this embodiment, because the movement stroke of the mounting head 30 in the X axis direction can be made to be small, it is possible to reduce the width (in the X axis direction) of the mounting apparatus 100 and thus achieve the size reduction of the mounting apparatus 100.

Further, in this embodiment, because the height sensor 7 is disposed between the suction nozzle 35 and the substrate camera 6 in the Y axis direction, it is possible to make the movement stroke in the Y axis direction smaller. As a result, it is possible to reduce the depth (in the Y axis direction) of the mounting apparatus 100 and thus achieve the size reduction of the mounting apparatus 100. It should be noted that as described above, in the case where the height sensor 7 is disposed on the front side as compared to the suction nozzle 35 or disposed on the rear side as compared to the substrate camera 6, a larger movement stroke in the Y axis direction may become necessary.

In the above description, the three members are linearly arranged in order of the suction nozzle 35, the height sensor 7, and the substrate camera 6 along the Y axis direction (direction perpendicular to the conveyance direction of the substrate S). On the other hand, the three members may be linearly disposed in order of the suction nozzle 35, the height sensor 7, and the substrate camera 6 along the X axis direction (conveyance direction of the substrate S). In this case, it is also possible to reduce the movement stroke of the mounting head 30 in the X axis direction and Y axis direction. As a result, it is possible to achieve the size reduction of the entire mounting apparatus 100.

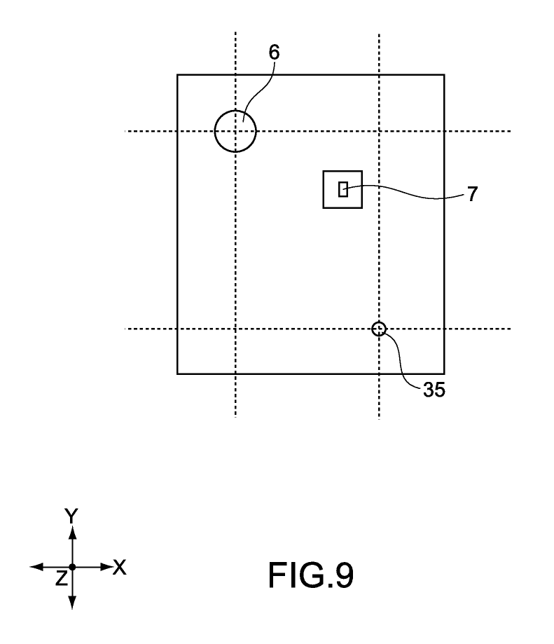

Subsequently, the position of the height sensor 7 with respect to the positions of the suction nozzle 35 and the substrate camera 6 will be described in more detail. FIG. 9 is a diagram for explaining the position of the height sensor 7 with respect to the positions of the suction nozzle 35 and the substrate camera 6.

First, the positional relationship between the suction nozzle 35 and the substrate camera 6 will be described. As shown in FIG. 9, in this example, the suction nozzle 35 and the substrate camera 6 are not disposed along the X axis direction (movement direction of the mounting head 30) and are not disposed along the Y axis direction (movement direction of the mounting head 30). In other words, the suction nozzle 35 and the substrate camera 6 may not necessarily be arranged along the X axis direction or the Y axis direction, and the positions of the suction nozzle 35 and the substrate camera 6 can be changed as necessary.

For example, the assumption is made that the height sensor 7 is added to the existing mounting apparatus 100 having the suction nozzle 35 and the substrate camera 6, and a warp detection function for the substrate S is further added to the mounting apparatus 100. In this case, the suction nozzle 35 and the substrate camera 6 in the existing mounting apparatus 100 may not be disposed along the X axis direction or the Y axis direction. Alternatively, in the case where the mounting apparatus 100 is newly produced, due to a restriction on an apparatus arrangement or the like, it may be impossible to arrange the suction nozzle 35 and the substrate camera 6 along the X axis direction or the Y axis direction.

For example, in such a case, from the viewpoint of suppressing an increase in the movement stroke of the mounting head 30, a position where the height sensor 7 is to be disposed will be described.

As indicated by broken lines in FIG. 9, on the XY plane, a line that passes through the center of the suction nozzle 35 and is parallel to the Y axis direction (movement direction of the mounting head 30) is drawn, and a line that passes through the center of the substrate camera 6 and is parallel to the Y axis direction is drawn. Further, on the XY plane, a line that passes through the center of the suction nozzle 35 and is parallel to the X axis direction (movement direction of the mounting head 30) is drawn, and a line that passes through the center of the substrate camera 6 and is parallel to the X axis direction is drawn.

The height sensor 7 is disposed in an area surrounded by the four lines described above. It should be noted that the suction nozzle 35, the substrate camera 6, and the height sensor 7 may be disposed in different positions in the height direction. By disposing the height sensor 7 in the area, it is possible to prevent the increase in the movement stroke of the mounting head 30 in the XY directions. As a result, it is possible to achieve the size reduction of the entire mounting apparatus 100.

Here, for example, in FIG. 9, when the position of the substrate camera 6 is moved rightward, the line that passes through the center of the substrate camera 6 and is parallel to the Y axis direction coincides with the line that passes through the center of the suction nozzle 35 and is parallel to the Y axis direction. In this case, the height sensor 7 is disposed at any position on the coincided line (see, FIGS. 6 and 7).

In the same way, in FIG. 9, when the position of the substrate camera 6 is moved forward (to the lower side in FIG. 9), the line that passes through the center of the substrate camera 6 and is parallel to the X axis direction coincides with the line that passes through the center of the suction nozzle 35 and is parallel to the X axis direction. In this case, the height sensor 7 is disposed at any position on the coincided line. It should be noted that in the case where the three members are linearly disposed along the X axis direction or the Y axis direction (movement directions of the mounting head 30), it is possible to minimize the movement stroke of the mounting head 30, which is particularly advantageous.

Typically, the height sensor 7 is disposed in the following area. That is, the height sensor 7 is disposed in an area surrounded by one or more lines that are parallel to the Y axis direction and pass through at least one of the positions of the suction nozzle 35 and the substrate camera 6 and one or more lines that are parallel to the X axis direction and pass through at least one of the positions of the suction nozzle 35 and the substrate camera 6.

### Various Modified Examples

In the example described above, the case where the plurality of suction nozzles 35 are provided is described, but the number of suction nozzles 35 is not particularly limited. For example, the number of suction nozzles 35 may be one. In the above description, the suction nozzles 35 are given as an example of the placement member, but the placement member is not limited to the suction nozzles 35. For example, the placement member may have such a form that the electronic component E is sandwiched from both sides and held.

It should be noted that the present disclosure can take the following configurations.

(1) A mounting apparatus, including:

a mounting head having a placement member that places an electronic component on a substrate, the mounting head being movable in a first direction and a second direction perpendicular to the first direction in a plane;

an image pickup unit disposed on a position where the image pickup unit is movable along with a movement of the mounting head and configured to take an image of an alignment mark provided on the substrate; and

a height measurement unit disposed in an area surrounded by one or more lines that are parallel to the first direction and pass through at least one of a position of the placement member and a position of the image pickup unit and one or more lines that are parallel to the second direction and pass through at least one of the position of the placement member and the position of the image pickup unit and configured to measure a height of the substrate.

(2) The mounting apparatus according to Item (1), in which

the placement member, the image pickup unit, and the height measurement unit are linearly arranged along one of the first direction and the second direction.

(3) The mounting apparatus according to Item (2), in which

the substrate is conveyed along the second direction, and

the placement member, the image pickup unit, and the height measurement unit are linearly arranged along the first direction.

(4) The mounting apparatus according to Item (2), in which

the substrate is conveyed along the second direction, and

the placement member, the image pickup unit, and the height measurement unit are linearly arranged along the second direction.

(5) The mounting apparatus according to any one of Items (1) to (4), further including

a movement body which is movable in the first direction and the second direction and to which the mounting head is attached, in which

the image pickup unit and the height measurement unit are disposed on a lower position of the movement body.

(6) A method of disposing members, including:

configuring a mounting head having a placement member that places an electronic component on a substrate so that the mounting head is movable in a first direction and a second direction perpendicular to the first direction in a plane;

disposing an image pickup unit that takes an image of an alignment mark provided on the substrate on a position where the image pickup unit is movable along with a movement of the mounting head; and

disposing a height measurement unit that measures a height of the substrate in an area surrounded by one or more lines that are parallel to the first direction and pass through at least one of a position of the placement member and a position of the image pickup unit and one or more lines that are parallel to the second direction and pass through at least one of the position of the placement member and the position of the image pickup unit.

(7) A method of manufacturing a substrate, including:

measuring a height of a substrate by a height measurement unit of a mounting apparatus including a mounting head which has a placement member that places an electronic component on the substrate and which is movable in a first direction and a second direction perpendicular to the first direction in a plane, an image pickup unit disposed on a position where the image pickup unit is movable along with a movement of the mounting head and configured to take an image of an alignment mark provided on the substrate, and the height measurement unit disposed in an area surrounded by one or more lines that are parallel to the first direction and pass through at least one of a position of the placement member and a position of the image pickup unit and one or more lines that are parallel to the second direction and pass through at least one of the position of the placement member and the position of the image pickup unit; and

placing an electronic component on the substrate by the placement member in accordance with the height of the substrate measured.

It should be understood that various changes and modifications to the presently preferred embodiments described herein will be apparent to those skilled in the art. Such changes and modifications can be made without departing from the spirit and scope of the present subject matter and without diminishing its intended advantages. It is therefore intended that such changes and modifications be covered by the appended claims.

The invention is claimed as follows:

1. A mounting apparatus, comprising:
a mounting head having a placement member that places an electronic component on a substrate, the mounting head being movable in a first direction and a second direction perpendicular to the first direction in a plane;
an image pickup unit disposed on a position where the image pickup unit is movable along with a movement of the mounting head and configured to take an image of an alignment mark provided on the substrate; and
a height measurement unit disposed in an area surrounded by one or more lines that are parallel to the first direction and pass through at least one of a position of the placement member and a position of the image pickup unit and one or more lines that are parallel to the second direction and pass through at least one of the position of the placement member and the position of the image pickup unit and configured to measure a height of the substrate.

2. The mounting apparatus according to claim 1, wherein
the placement member, the image pickup unit, and the height measurement unit are linearly arranged along one of the first direction and the second direction.

3. The mounting apparatus according to claim 2, wherein
the substrate is conveyed along the second direction, and
the placement member, the image pickup unit, and the height measurement unit are linearly arranged along the first direction.

4. The mounting apparatus according to claim 2, wherein
the substrate is conveyed along the second direction, and
the placement member, the image pickup unit, and the height measurement unit are linearly arranged along the second direction.

5. The mounting apparatus according to claim 1, further comprising
a movement body which is movable in the first direction and the second direction and to which the mounting head is attached, wherein
the image pickup unit and the height measurement unit are disposed on a lower position of the movement body.

6. A method of disposing members, comprising:
configuring a mounting head having a placement member that places an electronic component on a substrate so that the mounting head is movable in a first direction and a second direction perpendicular to the first direction in a plane;
disposing an image pickup unit that takes an image of an alignment mark provided on the substrate on a position where the image pickup unit is movable along with a movement of the mounting head; and
disposing a height measurement unit that measures a height of the substrate in an area surrounded by one or more lines that are parallel to the first direction and pass through at least one of a position of the placement member and a position of the image pickup unit and one or more lines that are parallel to the second direction and pass through at least one of the position of the placement member and the position of the image pickup unit.

7. A method of manufacturing a substrate, comprising:
measuring a height of a substrate by a height measurement unit of a mounting apparatus including a mounting head which has a placement member that places an electronic component on the substrate and which is movable in a first direction and a second direction perpendicular to the first direction in a plane, an image pickup unit disposed on a position where the image pickup unit is movable along with a movement of the mounting head and configured to take an image of an alignment mark provided on the substrate, and the height measurement unit disposed in an area surrounded by one or more lines that are parallel to the first direction and pass through at least one of a position of the placement member and a position of the image pickup unit and one or more lines that are parallel to the second direction and pass through at least one of the position of the placement member and the position of the image pickup unit; and
placing an electronic component on the substrate by the placement member in accordance with the height of the substrate measured.
